(19) United States
(12) Patent Application Publication
(10) Pub. No.: US 2024/0284629 A1
(43) Pub. Date: Aug. 22, 2024

(54) ASSEMBLING STRUCTURE

(71) Applicant: LITE-ON TECHNOLOGY CORPORATION, Taipei (TW)

(72) Inventors: Ya-Ting WANG, Taipei (TW); Wei-Hao LIANG, Taipei (TW)

(21) Appl. No.: 18/241,263

(22) Filed: Sep. 1, 2023

Related U.S. Application Data
(60) Provisional application No. 63/447,366, filed on Feb. 22, 2023.

(30) Foreign Application Priority Data
Jun. 13, 2023 (TW) 112121959

(51) Int. Cl. H05K 7/14; H02G 5/00

(52) U.S. Cl. CPC H05K 7/1489; H02G 5/00

(57) ABSTRACT

An assembling structure for assembling a connector on a frame is provided. The assembling structure includes a front bracket, a rear bracket, and a plurality of assembling parts. The front bracket and the rear bracket are disposed on opposite sides of the frame, and the assembling parts are configured to assemble the front bracket and the rear bracket. The frame has an upper frame and a lower frame, the connector is arranged between the upper frame and the lower frame by combining the front bracket, the rear bracket, and the assembling parts, and the positions of the front bracket, the rear bracket and the connector on the frame are adjustable.

This application claims the benefits of U.S. provisional application Ser. No. 63/447,366, filed Feb. 22, 2023 and Taiwan application Serial No. 112121959, filed Jun. 13, 2023, the subject matters of which are incorporated herein by reference.

### BACKGROUND OF THE INVENTION

### Field of the Invention

The invention relates in general to an assembling structure, and more particularly to a position-adjustable assembling structure.

### Description of the Related Art

Conventional busbar power connector, having high current performance and being capable of providing various configurations and function options, is applicable to various applications of power distribution. The busbar power connector can match actual output slot of typical power supply, increase reliability, and provide better performance.

However, conventional frame can only be used in a fixed-type busbar power connector. The busbar power connector is directly locked on the frame through screws, and its position is fixed. Therefore, to be adjusted to the position of actual output slot of the power supply, the busbar power connector needs to be re-designed.

### SUMMARY OF THE INVENTION

The invention is directed to a position-adjustable assembling structure for resolving the problems encountered in the busbar power connector.

According to one embodiment of the present invention, an assembling structure used to assemble a connector on a frame is provided. The assembling structure includes a first bracket, a second bracket, and a plurality of assembling parts. The first bracket and the second bracket are disposed on opposite sides of the frame, and the assembling parts are configured to assemble the first bracket and the second bracket. The frame has a first frame and a second frame, the connector is arranged between the first frame and the second frame by combining the first bracket, the second bracket, and the assembling parts, and the positions of the front bracket, the rear bracket and the connector on the frame are adjustable.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is an explosion diagram of position-adjustable assembling structure according to an embodiment of the invention.

FIGS. 2A and 2B are a front view and a rear view of the position-adjustable assembling structure of FIG. 1.

FIGS. 3A-3C respectively are reference diagrams of the position-adjustable assembling structure of FIG. 1 moving to distinct positions.

FIG. 4 is an explosion diagram of a position-adjustable assembling structure according to another embodiment of the invention.

FIGS. 5A and 5B are a front view and a rear view of the position-adjustable assembling structure of FIG. 4.

FIGS. 6A-6C respectively are reference diagrams of the position-adjustable assembling structure of FIG. 4 moving to distinct positions.

### DETAILED DESCRIPTION OF THE INVENTION

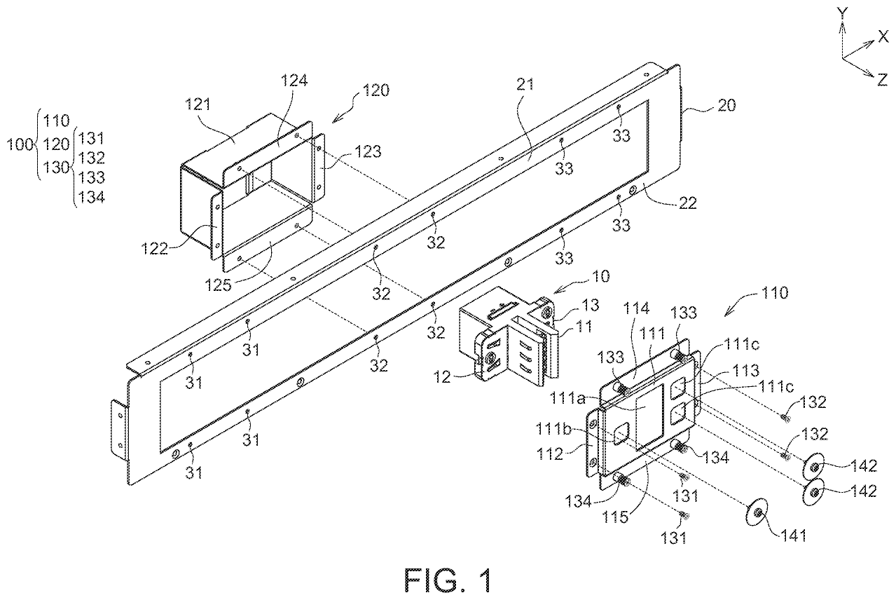

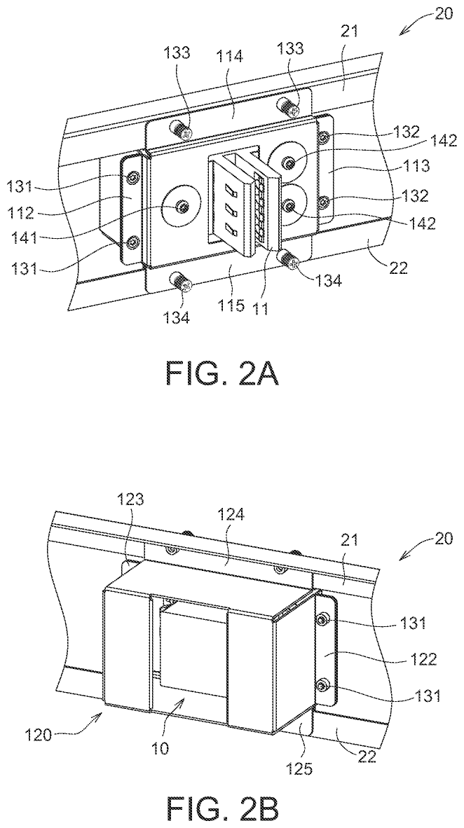

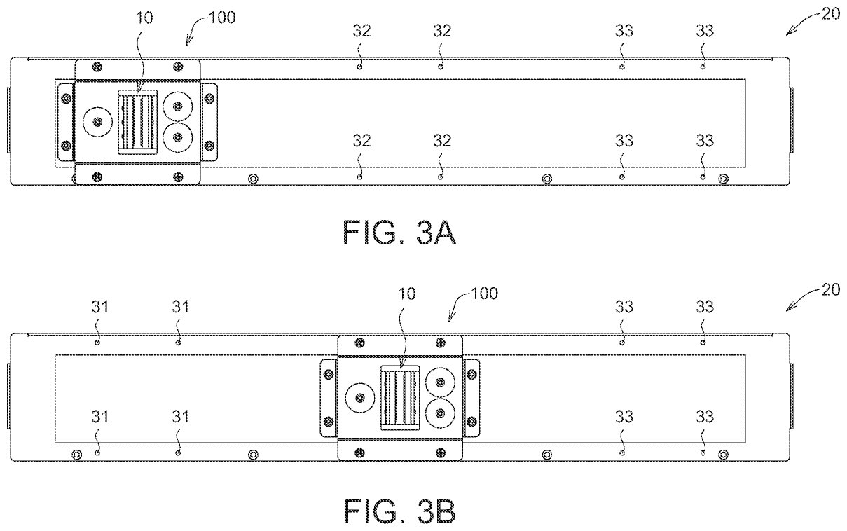

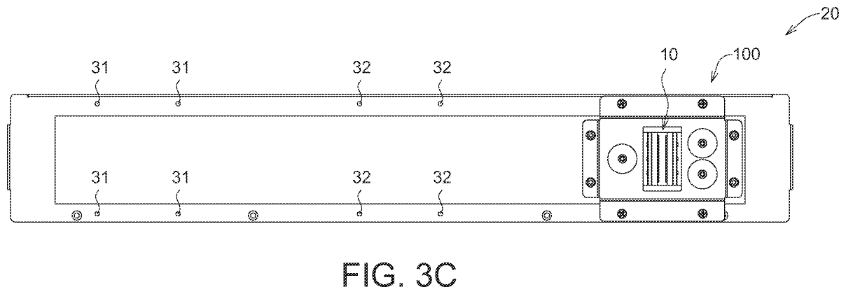

Refer to FIG. 1 to FIG. 3C. FIG. 1 is an explosion diagram of position-adjustable assembling structure 100 according to an embodiment of the invention. FIGS. 2A and 2B are a front view and a rear view of the position-adjustable assembling structure 100 of FIG. 1. FIGS. 3A-3C respectively are reference diagrams of the position-adjustable assembling structure 100 of FIG. 1 moving to distinct positions.

In an embodiment, the position-adjustable assembling structure 100 (here below referred as assembling structure 100) can be formed by the assembling structure 100 of a movable power connector (here below referred as connector 10) and is disposed on a frame 20. The connector 10 can be adjusted to any specified position on the same plane of the frame 20 according to actual needs. To move the movable power connector 10, the user only needs to release the assembling part 130 (such as the thumb screw) for allowing the assembling structure 100 to slide to the specified position on the frame 20 then fasten the assembling part 130 without having to dismount the movable power connector 10 and the assembling structure 100 from the frame 20 and then assemble them to the frame 20. Therefore, the assembly time and the time for adjusting the position of the connector 10 are reduced, and assembly efficiency can be increased.

Refer to FIG. 1. The assembling structure 100 is used to assemble a connector 10 on a frame 20. The assembling structure 100 includes a front bracket 110, a rear bracket 120 and a plurality of assembling parts 130. The front bracket 110 is arranged at the front side of the frame 20; the rear bracket 120 is arranged at the back side of the frame 20; the front bracket 110 and the rear bracket 120 are disposed on opposite sides of the frame 20. The assembling parts 130 are used to assemble the front bracket 110 and the rear bracket 120. The connector 10 is arranged on the frame 20 by combining the front bracket 110, the rear bracket 120 and the assembling parts 130, and the positions of the front bracket 110, the rear bracket 120 and the connector 10 on the frame 20 are adjustable.

Refer to FIG. 1. The frame 20 has an upper frame 21 (also referred as first frame) and a lower frame 22 (also referred as second frame); the connector 10 can be arranged between the upper frame 21 and the lower frame 22 by combining the front bracket 110, the rear bracket 120 and the assembling parts 130. In an embodiment, the front bracket 110 includes a first framework 111 and a first edge 112, a second edge 113, a third edge 114 and a fourth edge 115 that surround the first framework 111. The first framework 111 includes a first through hole 111a, a second through hole 111b and a third through hole 111c. The connector 10 has an electrical connection port 11 (also referred as an insertion piece or a clip) corresponding to the first through hole 111a. The electrical connection port 11 can be inserted to the first through hole 111a to be protruded from one side of the frame 20. The connector 10 has a first leaning surface 12, a second leaning surface 13, a first fastening member 141 and a second fastening member 142 (two are illustrated in the diagram) corresponding to the second through hole 111b and the third through hole 111c (two are illustrated in the diagram). The first fastening member 141 can pass through the second through hole 111b to be assembled on the first leaning surface 12, and the second fastening member 142 can pass through the third through hole 111c to be assembled on the second leaning surface 13.

Besides, the rear bracket 120 includes a second framework 121 and a first opposite edge 122, a second opposite edge 123, a third opposite edge 124 and a fourth opposite edge 125 that surround the second framework 121. The first edge 112 and the first opposite edge 122 overlap with each other and are fixed by a first fixing member 131 (two are illustrated in the diagram) of the assembling parts 130; the second edge 113 and the second opposite edge 123 overlap with each other and are fixed by a second fixing member 132 (two are illustrated in the diagram) of the assembling parts 130.

Also, the upper frame 21 is arranged between the third edge 114 and the third opposite edge 124, and the upper frame 21, the third edge 114 and the third opposite edge 124 overlap with each other and are fixed by a third fixing member 133 (two are illustrated in the diagram) of the assembling parts 130. The lower frame 22 is arranged between the fourth edge 115 and the fourth opposite edge 125, and the lower frame 22, the fourth edge 115 and the fourth opposite edge 125 overlap with each other and are fixed by a fourth fixing member 134 (two are illustrated in the diagram) of the assembling parts 130.

That is, the front bracket 110 and the rear bracket 120 can be arranged between the upper frame 21 and the lower frame 22 through the assembling parts 130 (each of the top, the bottom, the left and the right has two, but the invention is not limited thereto). Meanwhile, to meet the requirement of movability, the upper frame 21 and the lower frame 22 have several through hole groups 31-33 (such as three, but the invention is not limited thereto) correspondingly disposed at several positions (such as three, but the invention is not limited thereto) on the same plane, so that the front bracket 110 and the rear bracket 120 can move to one of the positions according to the user's requirement and the assembling parts 130 can be assembled to one of the through hole groups 31-33.

Refer to FIG. 1. The first to the fourth edges 112-115 are coplanar; the plane on which the first opposite edge 122 to the fourth opposite edge 125 are located (X-Y plane) is substantially parallel to the plane on which the first edge 112 to the fourth edge 115 are located (X-Y plane). Through such design, the front bracket 110 and the rear bracket 120 can be directly assembled on the frame 20 through the assembling parts 130 and will not come off the frame 20.

In an embodiment, for the user to conveniently move the connector 10, the third fixing member 133 and the fourth fixing member 134 can be realized by such as thumb screws, spring screws or quick release screws. The main function of the third fixing member 133 and the fourth fixing member 134 is for enabling the front bracket 110 and the rear bracket 120 to be assembled on the upper frame 21 and the lower frame 22. By releasing the third fixing member 133 and the fourth fixing member 134, the user can adjust the connector 10 to any desired position without having to dismount the connector 10, the front bracket 110 and the rear bracket 120 from the frame 20 then assemble them on the frame 20. Therefore, the assembly time and the time for adjusting the position of the connector 10 are reduced, and assembly efficiency can be increased.

Refer to FIGS. 3A-3C. There are three through hole groups 31-33 corresponding to three positions (but is not limited thereto) of the upper frame 21 and the lower frame 22 on the same plane. As disclosed above, when the user needs to move the connector 10 and the assembling structure 100, the user only needs to release the third fixing member 133 and the fourth fixing member 134 and slide the fixing structure 100 to the specified position (such as the left position, the middle position and the right position) on the frame 20 and then tighten the third fixing member 133 and the fourth fixing member 134 again. Thus, the user can correspondingly adjust the position of the connector 10 according to actual output slot (not illustrated) of the power supply.

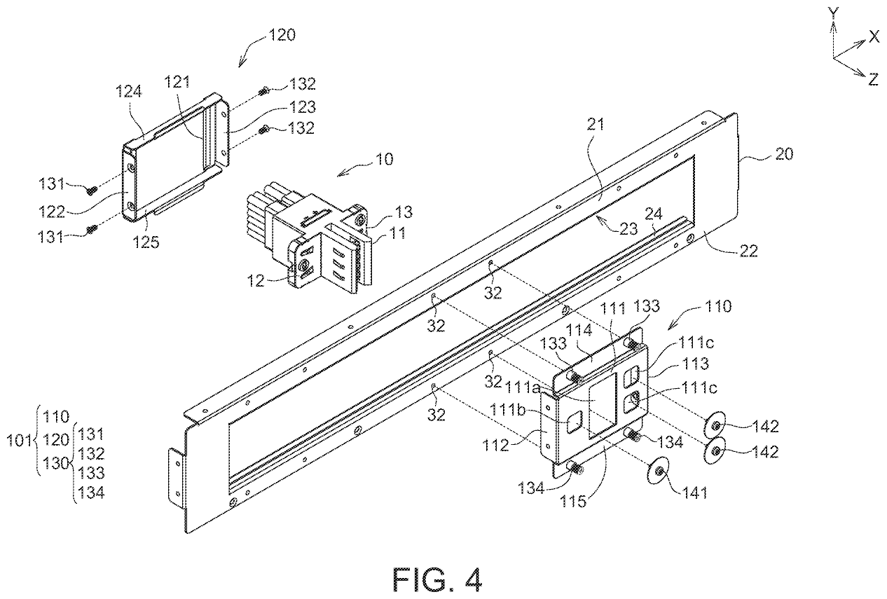

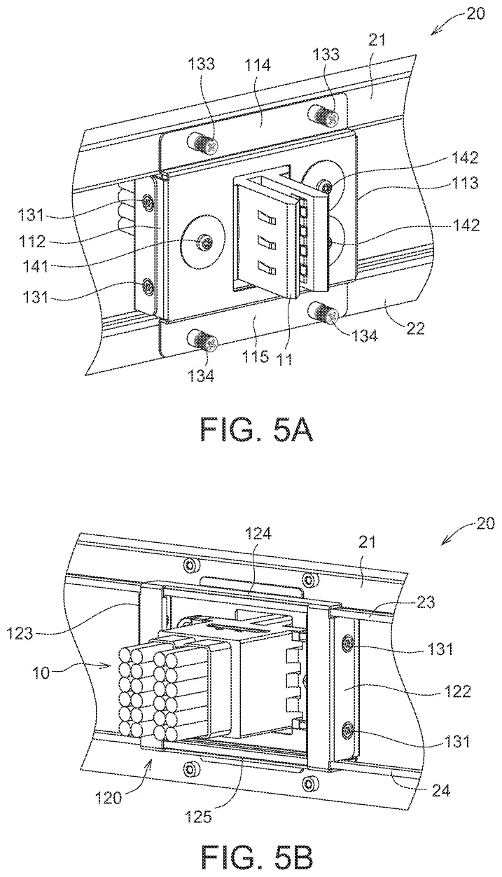

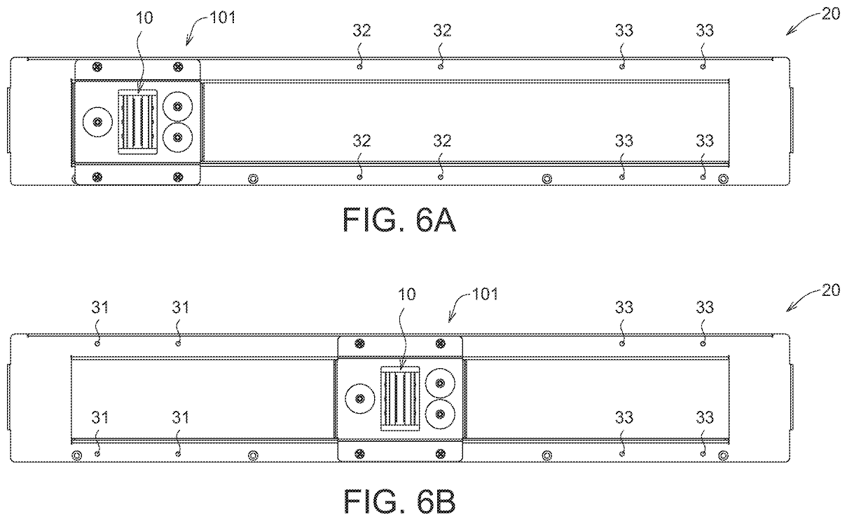

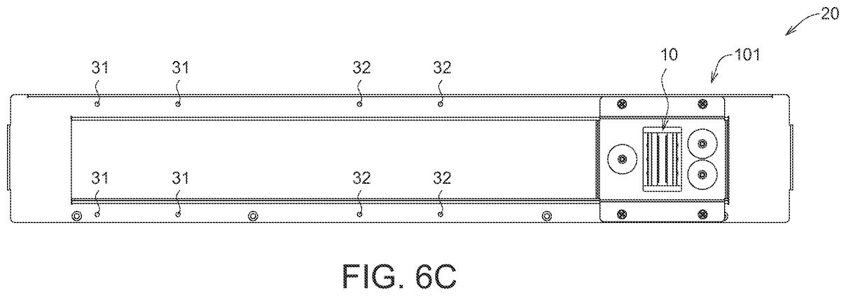

Refer to FIG. 4 to FIG. 6C. FIG. 4 is an explosion diagram of a position-adjustable assembling structure 101 according to another embodiment of the invention. FIGS. 5A and 5B are a front view and a rear view of the position-adjustable assembling structure 101 of FIG. 4. FIGS. 6A-6C respectively are reference diagrams of the position-adjustable assembling structure 101 of FIG. 4 moving to distinct positions.

Refer to FIG. 4. The assembling structure 101 is used to assemble a connector 10 on a frame 20. The assembling structure 100 includes a front bracket 110, a rear bracket 120 and a plurality of assembling parts 130. The front bracket 110 is arranged at the front side of the frame 20; the rear bracket 120 is arranged at the back side of the frame 20. The assembling parts 130 is used to assemble the front bracket 110 and the rear bracket 120. The connector 10 can be arranged on the frame 20 by combining the front bracket 110, the rear bracket 120 and the assembling parts 130, and the positions of the front bracket 110, the rear bracket 120 and the connector 10 on the frame 20 are adjustable. The present embodiment is different from the above embodiment in that: in the present embodiment, one side of the upper frame 21 of the frame 20 has a first slide rail 23, and one side of the lower frame 22 has a second slide rail 24, wherein the first slide rail 23 is substantially perpendicular to the upper frame 21, and the second slide rail 24 is substantially perpendicular to the lower frame 22. That is, the first slide rail 23 and the second slide rail 24 respectively are disposed on opposite sides of the upper frame 21 and the lower frame 22.

The front bracket 110 includes a first framework 111 and a first edge 112, a second edge 113, a third edge 114 and a fourth edge 115 that surround the first framework 111. The rear bracket 120 includes a second framework 121 and a first opposite edge 122, a second opposite edge 123, a third opposite edge 124 and a fourth opposite edge 125 that surround the second framework 121. In an embodiment, the first edge 112 and the second edge 113 face the back side of the frame 20, and the first opposite edge 122 and the second opposite edge 123 face the front side of the frame 20. That is, the first edge 112 and the second edge 113 are substantially perpendicular to the first framework 111 and are protruded backwards; the first opposite edge 122 and the second opposite edge 123 are substantially perpendicular to the second framework 121 and are protruded forwards. In FIG. 4, the first edge 112 and the second edge 113 are parallel with each other (on Y-Z plane) and are perpendicular to the axial direction (on X-Z plane) of the first slide rail 23 and the second slide rail 24 (non-coplanar); the third edge 114 and the fourth edge 115 are parallel with each other (on X-Y plane) and are perpendicular to the axial direction (on X-Z plane) of the first slide rail 23 and the second slide rail 24 (non-coplanar). The first edge 112, the second edge 113, the first opposite edge 122 and the second opposite edge 123 can be arranged between the first slide rail 23 and the second slide rail 24. Refer to FIG. 1. The first edge 112 to the fourth edge 115 are coplanar; the plane on which the first opposite edge 122 to the fourth opposite edge 125 are located (on X-Y plane) is substantially parallel to the plane on which the first edge 112 to the fourth edge 115 are located (on X-Y plane), therefore the front bracket 110 and the rear bracket 120 can be directly assembled on the frame 20 and will not come off the frame 20.

In an embodiment, the first edge 112 and the first opposite edge 122 overlap with each other and are fixed by a first fixing member 131 (two are illustrated in the diagram) of the assembling parts 130, and the second edge 113 and the second opposite edge 123 overlap with each other and are fixed by a second fixing member 132 (two are illustrated in the diagram) of the assembling parts 130.

Moreover, the first slide rail 23 and the third opposite edge 124 overlap with each other, and the second slide rail 24 and the fourth opposite edge 125 overlap with each other, so that the rear bracket 120 can be arranged on the first slide rail 23 and the second slide rail 24 through the third opposite edge 124 and the fourth opposite edge 125 and the rear bracket 120 can slide horizontally without coming off. Besides, the third edge 114 and the upper frame 21 overlap with each other and are fixed by a third fixing member 133 (two are illustrated in the diagram) of the assembling parts 130; the second slide rail 24 and the fourth opposite edge 125 overlap with each other, the fourth edge 115 and the lower frame 22 overlap with each other and are fixed by a fourth fixing member 134 (two are illustrated in the diagram) of the assembling parts 130. That is, the front bracket 110 and the rear bracket 120 can be arranged between the upper frame 21 and the lower frame 22 through the assembling parts 130 (two on each of the top, the bottom, the left and the right, but the invention is not limited thereto).

In an embodiment, for the user to conveniently move the connector 10, the third fixing member 133 and the fourth fixing member 134 can be realized by such as thumb screws, spring screws or quick release screws. The main function of the third fixing member 133 and the fourth fixing member 134 is for enabling the front bracket 110 and the rear bracket 120 to be assembled on the upper frame 21 and the lower frame 22. By releasing the third fixing member 133 and the fourth fixing member 134, the user can adjust the connector 10 to any desired position without having to dismount the connector 10, the front bracket 110 and the rear bracket 120 from the frame 20 and then assemble them on the frame 20 again. Therefore, the assembly time and the time for adjusting the position of the connector 10 are reduced, and assembly efficiency can be increased.

Refer to FIGS. 6A-6C. There are three through hole groups 31-33 corresponding to three positions (but is not limited thereto) of the upper frame 21 and the lower frame 22 on the same plane. As disclosed above, when the user needs to move the connector 10 and the fixing structure 101, the user only needs to release the third fixing member 133 and the fourth fixing member 134 and slide the fixing structure 101 to the specified position (such as the left position, the middle position and the right position) on the frame 20 and then tighten the third fixing member 133 and the fourth fixing member 134 again. Thus, the user can correspondingly adjust the position of the connector 10 according to actual output slot (not illustrated) of the power supply.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An assembling structure for assembling a connector on a frame, the assembling structure comprising:
a first bracket;
a second bracket, wherein the second bracket and the first bracket are disposed on opposite sides of the frame; and
a plurality of assembling parts configured to assemble the first bracket and the second bracket,
wherein the frame has a first frame and a second frame, the connector is arranged between the first frame and the second frame by combining the first bracket, the second bracket and the assembling parts, and positions of the first bracket, the second bracket and the connector on the frame are adjustable.

2. The assembling structure according to claim 1, wherein the first bracket comprises a first framework and a first edge, a second edge, a third edge and a fourth edge that surround the first framework.

3. The assembling structure according to claim 2, wherein the second bracket comprises a second framework and a first opposite edge, a second opposite edge, a third opposite edge and a fourth opposite edge that surround the second framework, the first edge and the first opposite edge overlap with each other and are fixed by a first fixing member of the assembling parts, and the second edge and the second opposite edge overlap with each other and are fixed by a second fixing member of the assembling parts.

4. The assembling structure according to claim 3, wherein the first frame is arranged between the third edge and the third opposite edge, and the first frame, the third edge and the third opposite edge overlap with each other and are fixed by a third fixing member of the assembling parts.

5. The assembling structure according to claim 4, wherein the second frame is arranged between the fourth edge and the fourth opposite edge, and the second frame, the fourth edge and the fourth opposite edge overlap with each other and are fixed by a fourth fixing member of the assembling parts.

6. The assembling structure according to claim 1, wherein one side of the first frame has a first slide rail, one side of the second frame has a second slide rail, the first slide rail is substantially perpendicular to the first frame, and the second slide rail is substantially perpendicular to the second frame.

7. The assembling structure according to claim 6, wherein the first bracket comprises a first framework and a first edge, a second edge, a third edge and a fourth edge that surround the first framework, the second bracket comprises a second framework and a first opposite edge, a second opposite edge, a third opposite edge and a fourth opposite edge that surround the second framework, the first edge and the first opposite edge overlap with each other and are fixed by a first fixing member of the assembling parts, and the second edge and the second opposite edge overlap with each other and are fixed by a second fixing member of the assembling parts.

8. The assembling structure according to claim 7, wherein the first slide rail and the third opposite edge overlap with each other, the second slide rail and the fourth opposite edge overlap with each other, so that the second bracket leans on the first slide rail and the second slide rail through the third opposite edge and the fourth opposite edge.

9. The assembling structure according to claim 7, wherein the third edge and the first frame overlap with each other and are fixed by a third fixing member of the assembling parts, and the fourth edge and the second frame overlap with each other and are fixed by a fourth fixing member of the assembling parts.

10. The assembling structure according to claim 1, wherein the first frame and the second frame have a plurality of through hole groups correspondingly disposed at a plurality of positions on a same plane, so that the first bracket and the second bracket is suitable to be moved to one of the positions and fixed on one of the through hole groups by the assembling parts.

11. The assembling structure according to claim 6, wherein the first frame and the second frame have a plurality of through hole groups correspondingly disposed at a plurality of positions on the same plane, so that the first bracket and the second bracket can be moved to one of the positions and fixed on one of the through hole groups by the assembling parts.

12. The assembling structure according to claim 2, wherein the first edge, the second edge, the third edge and the fourth edge are coplanar.

13. The assembling structure according to claim 12, wherein a plane on which the first opposite edge to the fourth opposite edge are located is substantially parallel to a plane on which the first edge to the fourth edge are located.

14. The assembling structure according to claim 7, wherein the first edge and the second edge are parallel with each other and are perpendicular to an axial direction of the first slide rail and the second slide rail, and the third edge and the fourth edge are parallel with each other and are perpendicular to the axial direction of the first slide rail and the second slide rail.

15. The assembling structure according to claim 14, wherein the first edge, the second edge, the first opposite edge and the second opposite edge are arranged between the first slide rail and the second slide rail.
